(19) United States
(12) Patent Application Publication
(10) Pub. No.: US 2013/0114196 A1
(43) Pub. Date: May 9, 2013

(54) FIXING STRUCTURE FOR DISPLAY PANEL AND METHOD OF FIXING

(71) Applicant: Hsi-ming Chen, Tokyo (JP)

(72) Inventor: Hsi-ming Chen, Tokyo (JP)

(73) Assignee: NEC Display Solutions, Ltd., Tokyo (JP)

(21) Appl. No.: 13/700,439

(22) PCT Filed: May 31, 2010
(86) PCT No.: PCT/JP2010/003631

§ 371 Date: Jan. 4, 2013

(51) Int. Cl. H05K 7/14

(52) U.S. Cl. CPC H05K 7/1417
USPC 361/679.01; 29/428

(57) ABSTRACT

A fixing structure for a display panel includes first, second, and third chassis members. The first chassis member includes a first corner securing portion secured to two side surfaces on an outer periphery side of a first corner portion of the display panel. The second chassis member includes a second corner securing portion secured to two side surfaces on an outer periphery side of a second corner portion of the display panel adjacent to the first corner portion. The third chassis member includes an opposing side securing portion secured to a middle portion of a side surface on an outer periphery side of the display panel that opposes a side surface on an outer periphery side that is sandwiched between the first corner portion and the second corner portion. The first, second, and third chassis members are coupled to each other at a back surface side of the display panel.

### TECHNICAL FIELD

The present invention relates to a fixing structure for a display panel and a method of fixing.

### BACKGROUND ART

Conventionally, in a display device such as a liquid crystal television or the like, various fixing structures are known that can fix a liquid crystal panel that is a display panel even if it is not provided with screw fastening holes for mounting.

For example, Patent Document 1 discloses a liquid crystal panel fixation structure that holds a liquid crystal module (display panel) in the state of covering the back surface and left, right, top and bottom side surfaces with a metal shield plate, pinches it from the front surface side with a front cabinet that exposes the screen of this liquid crystal module to the outside, and screw mounts this front cabinet and the shield plate with a metal upper panel holder and a lower panel holder.

Also, Patent Document 2 discloses a frame structure of a display panel that constitutes a frame body that is formed in an annular shape enclosing a liquid crystal cell including an LCD panel (LCD) and its peripheral circuits and the like, and has hollow grooves into which the outer peripheral edges of the liquid crystal cell fit on its inner peripheral surface, with this frame body dividable in a circumferential direction, and an engaging projection is formed at one of pair each of end faces of the divided frame bodies, and an engaging recess is formed at the other end.

This frame structure is fixed by screws via holes that are provided in a mounting piece that is provided in each frame body.

Also, Patent Document 3 discloses a video display device that fixes a plasma display panel (PDP) that is a display panel to a panel supporting thin plate via a strong double-coated adhesive tape, and that screw fixes screw portions that are provided at the four corner portions of the panel supporting thin plate and an X-shaped main body that spans these screw portions in a diagonal shape.

### PRIOR ART DOCUMENTS

### Patent Documents

[Patent Document 1] Japanese Unexamined Patent Application, First Publication No. 2008-216820

[Patent Document 2] Japanese Unexamined Patent Application, First Publication No. H07-146656

[Patent Document 3] Japanese Unexamined Patent Application, First Publication No. H11-338370

### SUMMARY OF THE INVENTION

### Problem to be Solved by the Invention

However, in the conventional fixing structures for a display panel and methods of fixing given above, there have been the following problems.

In the technology that is disclosed in Patent Document 1, since the display panel is fixed with the back surface and the top, bottom left, and right side surfaces thereof being covered by the shield plate, it is necessary to manufacture the size of the shield plate based on the maximum value of the dimensional tolerance of the outer dimension of the liquid crystal panel, and so looseness and positional shifting occurs in a range of the dimensional tolerance, and so there is the risk of accurate fixing not being possible.

Also, in the technology disclosed in Patent Document 2, since the frame body is formed in an annular shape enclosing a liquid crystal cell, similarly to the case of Patent Document 1, looseness and positional shifting occurs in a range of the dimensional tolerance of the liquid crystal panel, and so there is the risk of accurate fixing not being possible.

Also, in the technology disclosed in Patent Document 3, since the method of fixing with the panel supporting thin plate consists of fixing with double-coated adhesive tape, positional alignment and attachment work takes time, and so there is the problem of not being able to accurately fix the position of fixing the PDP.

The present invention has been achieved in view of the above circumstances, and has as its object to provide a fixing structure for fixing a display panel and a method of fixing that can accurately fix a display panel even if it is a display panel that does not have thread fastening holes for attachment.

### Means for Solving the Invention

In order to solve the aforementioned problems, a fixing structure for a display panel according to the present invention is for fixing the display panel having a rectangular plate shape and performing image display at a front side, and includes: a first chassis member that includes at one end portion a first corner securing portion secured to two side surfaces on an outer periphery side of a first corner portion of the display panel; a second chassis member that includes at one end portion a second corner securing portion secured to two side surfaces on an outer periphery side of a second corner portion of the display panel that is adjacent to the first corner portion; and a third chassis member that includes at one end portion an opposing side securing portion secured to a middle portion of a side surface on an outer periphery side of the display panel that opposes a side surface on an outer periphery side that is sandwiched between the first corner portion and the second corner portion, other end portions of the first chassis member, the second chassis member, and the third chassis member are coupled to each other at a back surface side of the display panel.

According to the fixing structure for a display panel of the present invention, the first corner securing portion, the second corner securing portion, and the opposing side securing portion that are respectively provided at each one end portion of the first chassis member, the second chassis member and the third chassis member are secured to the side surfaces on the outer periphery side of the display panel at the first corner portion, the second corner portion, and the middle portion of the side surface on the outer periphery side that is opposite the side surface of the outer periphery side that is sandwiched between the first corner portion and the second corner portion of the display panel, and in this state, each other end side portion of the first chassis member, the second chassis member, and the third chassis member is coupled at the back surface side of the display panel, and thereby, it is possible to fix the display panel by the first chassis member, the second chassis member and the third chassis member.

Also, in the fixing structure for a display panel according to the present invention, the first chassis member may include at the one end portion a first resilient sandwiching portion that sandwiches the display panel by causing a resilient force to act in a plate thickness direction of the display panel at the first corner portion, the second chassis member may include at the one end portion a second resilient sandwiching portion that sandwiches the display panel by causing a resilient force to act in the plate thickness direction of the display panel at the second corner portion, and the opposing side securing portion may include at the one end portion a third resilient sandwiching portion that sandwiches the display panel by causing a resilient force to act in the plate thickness direction of the display panel at the middle portion. In this case, at the first corner securing portion, the second corner securing portion, and the opposing side securing portion, the display panel is sandwiched in a state of a resilient force being applied in the plate thickness direction by the first resilient sandwiching portion, the second resilient sandwiching portion, and the third resilient sandwiching portion. For this reason, it is possible to ensure that the positions of the first chassis member, the second chassis member, and the third chassis member do not shift with respect to the display panel, while coupling the first chassis member, the second chassis member, and the third chassis member.

Also, in the fixing structure for a display panel according to the present invention, a first coupling fixing portion may be provided at the other end portions of the first chassis member and the second chassis member, which changes an opposing distance between the first corner securing portion and the second corner securing portion, and couples the first chassis member and the second chassis member with each other at the back surface side of the display panel to form a coupled body including the first chassis member and the second chassis member, and a second coupling fixing portion may be provided at the other end portion of at least either one of the first chassis member and the second chassis member, and at the other end portion of the third chassis member, which changes an opposing distance between the first corner securing portion and second corner securing portion, and the opposing side securing portion, and couples the coupled body and the third chassis member with each other at the back surface side of the display panel.

In this case, it is possible to constitute the coupled body by mutually coupling the first chassis member and the second chassis member in the state of the first corner securing portion and the second corner securing portion being secured to the side surface on the outer periphery side of the display panel by the first coupling fixing portion. Also, it is possible to mutually couple the coupled body and the third chassis member in the state of the first corner securing portion and second corner securing portion, and the opposing side securing portion being secured to the side surface on the outer periphery side of the display panel by the second coupling fixing portion.

Thereby, since it is possible, after reliably securing to one of the side surfaces of the display panel in the opposed direction, to easily secure to the other in the opposing direction, it is possible to easily realize a good secured state without looseness.

Also, in the fixing structure for a display panel that includes the first coupling fixing portion and the second coupling fixing portion according to the present invention, the first coupling fixing portion may include a first displacement guiding mechanism that guides relative displacement of the first chassis member and the second chassis member in a direction in which the first chassis member and the second chassis member are opposed to each other, and the second coupling fixing portion may include a second displacement guiding mechanism that guides relative displacement of the coupled body and the third chassis member in a direction in which the coupled body and the third chassis member are opposed to each other.

In this case, since the first coupling fixing portion includes the first displacement guiding mechanism, when performing coupling using the first coupling fixing portion, it is possible to guide the relative displacement of the first chassis member and the second chassis member in the direction in which they are opposed to each other, and so changing the opposing distance is easy. Also, since the second coupling fixing portion includes the second displacement guiding mechanism, when performing coupling using the second coupling fixing portion, it is possible to guide the relative displacement of the coupled body and the second chassis member in the direction in which they are opposed to each other, and so changing the opposing distance is easy.

Also, in the fixing structure for a display panel according to the present invention, the first resilient sandwiching portion, the second resilient sandwiching portion, and the opposing side resilient sandwiching portion may include a flat spring portion that causes the resilient force to act.

In this case, since the first resilient sandwiching portion, the second resilient sandwiching portion, and the third resilient sandwiching portion include a flat spring portion, it is easy to form the first resilient sandwiching portion, the second resilient sandwiching portion, and the third resilient sandwiching portion respectively to be integrated with the first corner securing portion, the second corner securing portion, and the opposite side securing portion, and so a reduction in size and cost reduction become easy.

A method of fixing a display panel according to the present invention is for fixing a display panel having a rectangular shape and performing image display at a front side using a fixing chassis, the fixing chassis including a first chassis member, a second chassis member, and a third chassis member that can be mutually coupled and can be secured to side surfaces on an outer periphery side of the display panel, and includes: a first step of securing the first chassis member to a first corner portion of the display panel, and securing the second chassis member to a second corner portion of the display panel that is adjacent to the first corner portion; a second step of forming a coupled body including the first chassis member and the second chassis member by coupling the first chassis member and the second chassis member respectively secured to the display panel in the first step, at a back surface side of the display panel, in a state of being secured to at least a mutually opposed pair of side surfaces on the outer periphery side of the display panel by adjusting an opposing distance between the first chassis member and the second chassis member; a third step of securing the third chassis member to a middle portion of an outer periphery portion of the display panel that opposes an outer periphery portion sandwiched between the first corner portion and the second corner portion; and a fourth step of coupling the coupled body and the third chassis member with each other at the back surface side of the display panel in a state of the coupled body formed in the second step and the third chassis member secured to the middle portion in the third step being respectively secured to the first corner portion and the second corner portion, and a side surface on the outer periphery side at the middle portion by adjusting an opposing distance between the coupled body and the third chassis member.

According to the fixing method for a display panel of the present invention, after securing the first chassis member and the second chassis member to the first corner portion and the second corner portion of the display panel, respectively, in the first step, the coupled body is formed in the second step by mutually coupling the first chassis member and the second chassis member at the back surface side of the display panel in the state of being secured to at least a mutually opposed pair of side surfaces on the outer periphery side of the display panel by adjusting the mutually opposing distance. Then, in the third step, the third chassis member is secured to the middle portion of the outer periphery portion opposite the outer periphery portion that is sandwiched between the first corner portion and the second corner portion. Then, in the fourth step, in the state where the opposing distance between the coupled body that was formed in the second step and the third chassis member that was pressed against the middle portion in the third step is adjusted, and the coupled body and the third chassis member are respectively secured to the side surfaces on the outer periphery side of the display panel, they are coupled at the back surface side of the display panel. Thereby, it is possible to fix the display panel by the first chassis member, the second chassis member, and the third chassis member.

Also, according to this method, it is possible to form a fixing structure for a display panel by the present invention.

### Effect of the Invention

According to the fixing structure for a display panel and method of fixing therefor of the present invention, since it is possible to fix a display panel with the first chassis member, the second chassis member, and the third chassis member being coupled at the back surface side of the display panel, in the state of being respectively secured to the first corner portion, the second corner portion, and the side surface on the outer periphery side of the middle portion of the side surface the outer periphery side that opposes the side surface on the outer periphery side that is sandwiched therebetween, it is possible to exhibit the effect of being able to accurately and easily perform the fixing even for a display panel that does not have screw fastening holes for mounting.

### BRIEF DESCRIPTION OF THE DRAWINGS

FIG. 1 is a perspective assembly diagram that shows a fixing structure for a display panel according to an exemplary embodiment of the present invention.

FIG. 2A is a partial enlarged diagram of portion A in FIG. 1.

FIG. 2B is a partial enlarged diagram from view B in FIG. 1.

FIG. 3 is an exploded perspective view that shows the constitution of a first chassis member and a second chassis member that are used for the fixing structure for a display panel according to the exemplary embodiment of the present invention.

FIG. 4A is a cross-sectional diagram taken along C₁-C₁ in FIG. 3.

FIG. 4B is a diagram from view C₂ in FIG. 3.

FIG. 5A is a cross-sectional diagram taken along D₁-D₁ in FIG. 3.

FIG. 5B is a diagram from view D₂ in FIG. 3.

FIG. 5C is a diagram from view E in FIG. 5A.

FIG. 6 is an exploded perspective view that shows the constitution of a first coupling fixing portion of the fixing chassis used for the fixing structure for a display panel according to the exemplary embodiment of the present invention.

FIG. 7 is an exploded perspective view that shows the constitution of a coupled body of the fixing chassis and a third chassis member used for the fixing structure for a display panel according to the exemplary embodiment of the present invention.

FIG. 8 is a diagram from view G in FIG. 7.

FIG. 9A is a cross-sectional diagram taken along H-H in FIG. 7.

FIG. 9B is a diagram from view J in FIG. 9A.

FIG. 9C is a diagram from view K in FIG. 9A.

### EMBODIMENTS FOR CARRYING OUT THE INVENTION

Hereinbelow, exemplary embodiment of the present invention shall be described with reference to the appended drawings.

First, a fixing structure for a display panel according to the exemplary embodiment of the present invention shall be described.

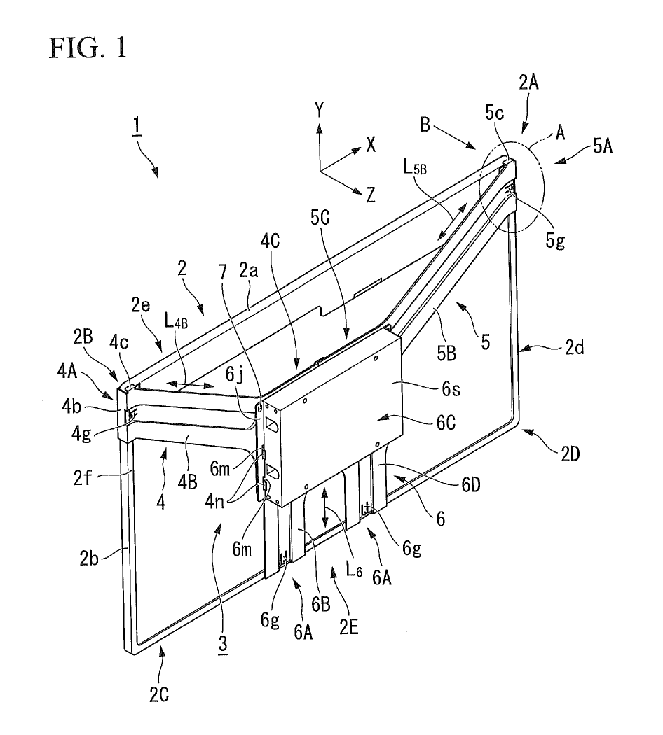

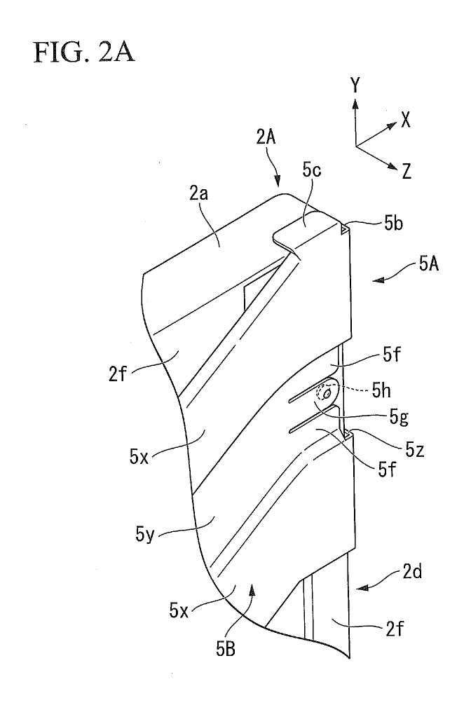

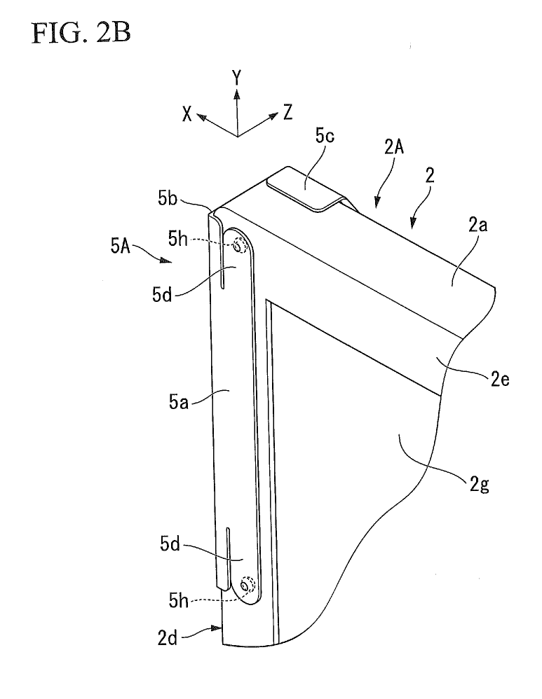

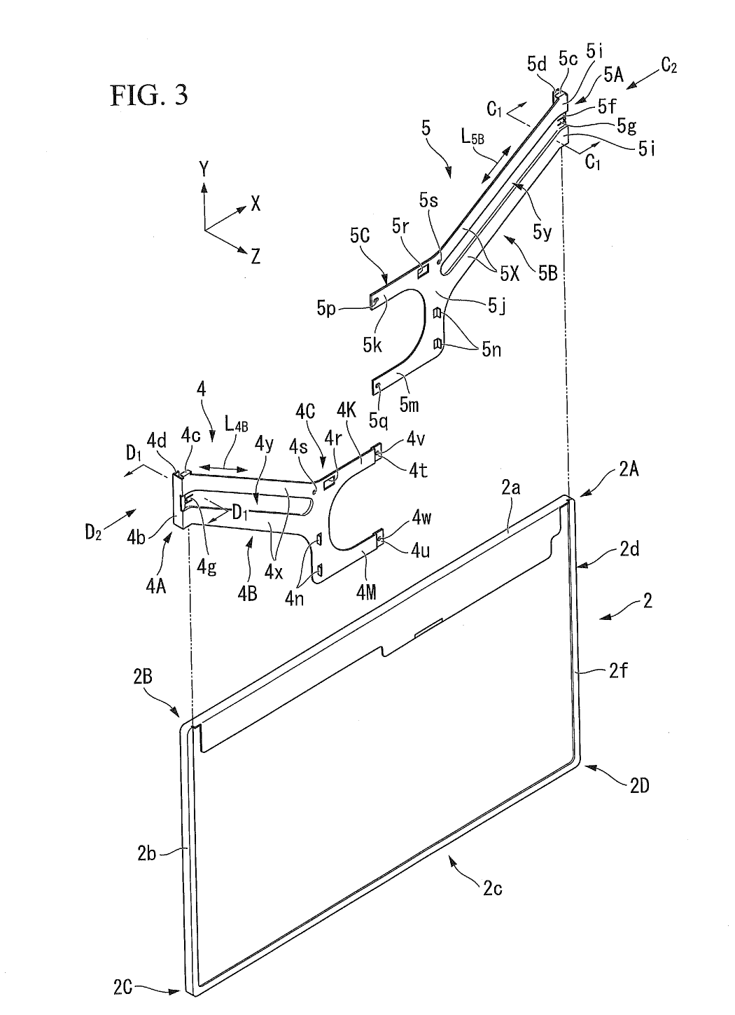

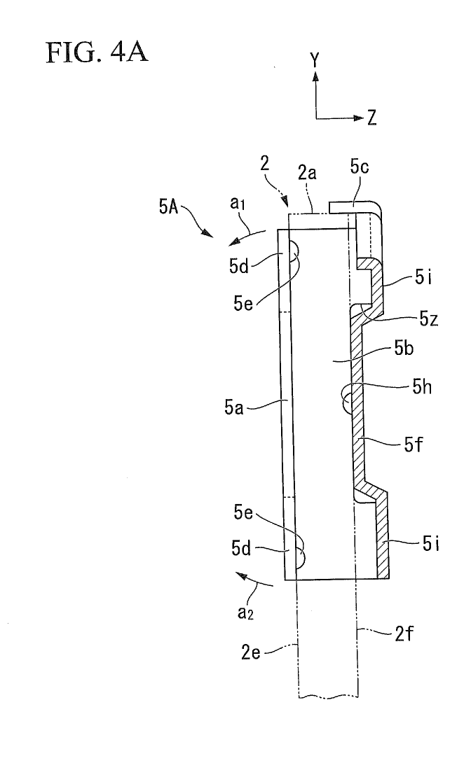

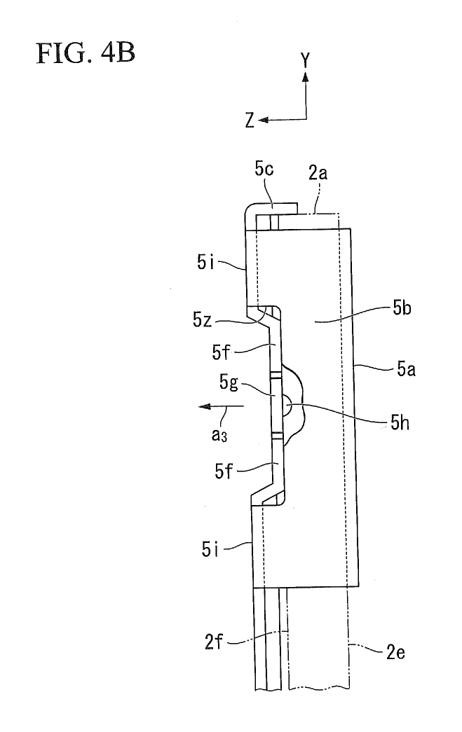

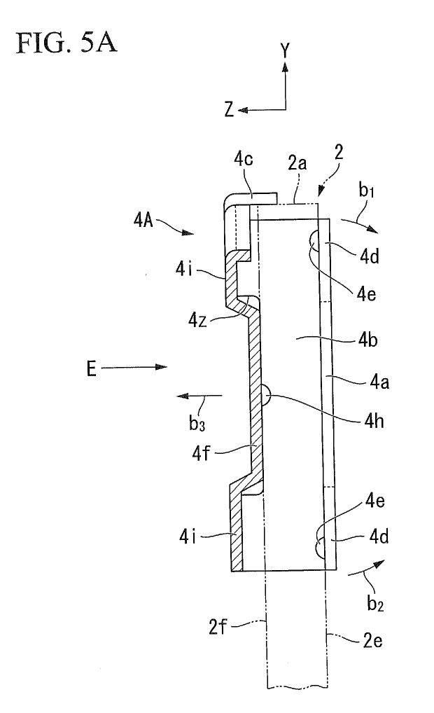

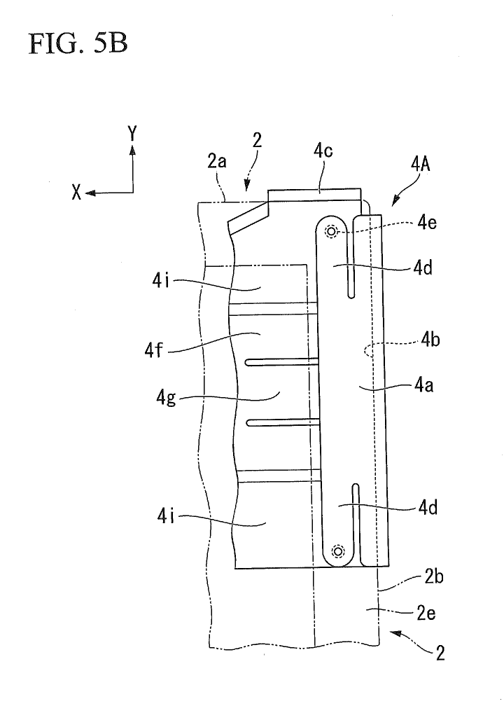

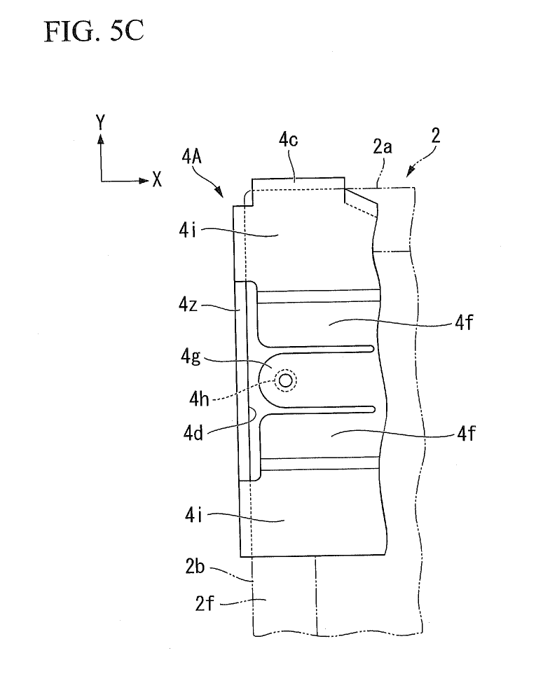

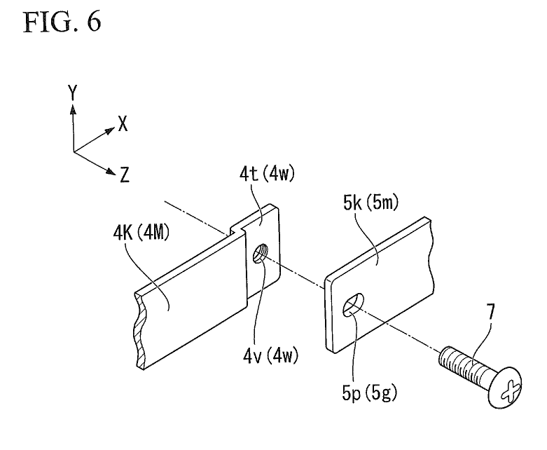

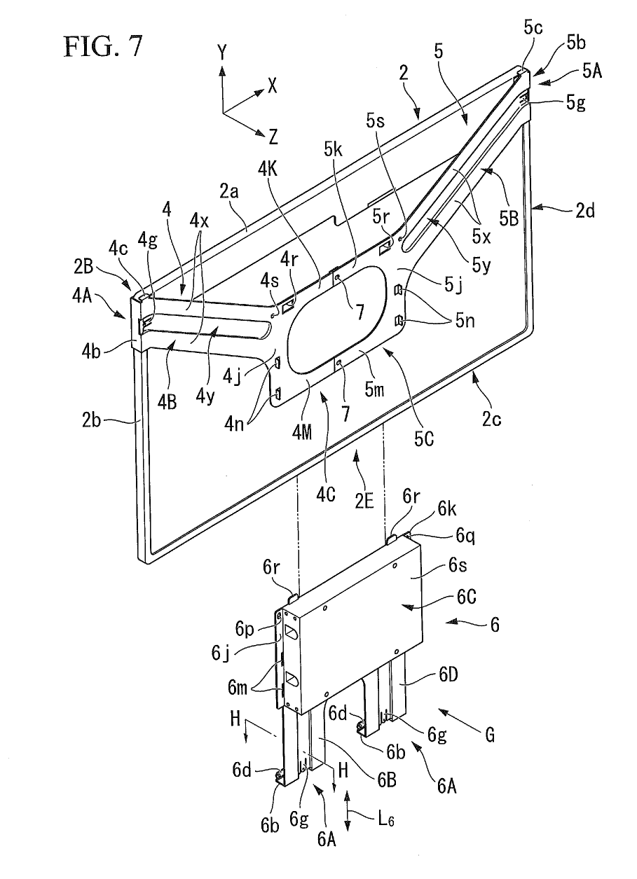

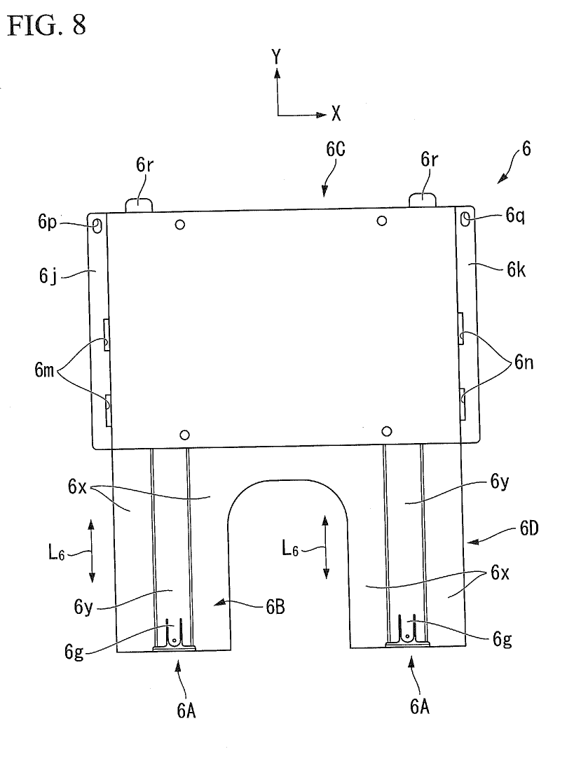

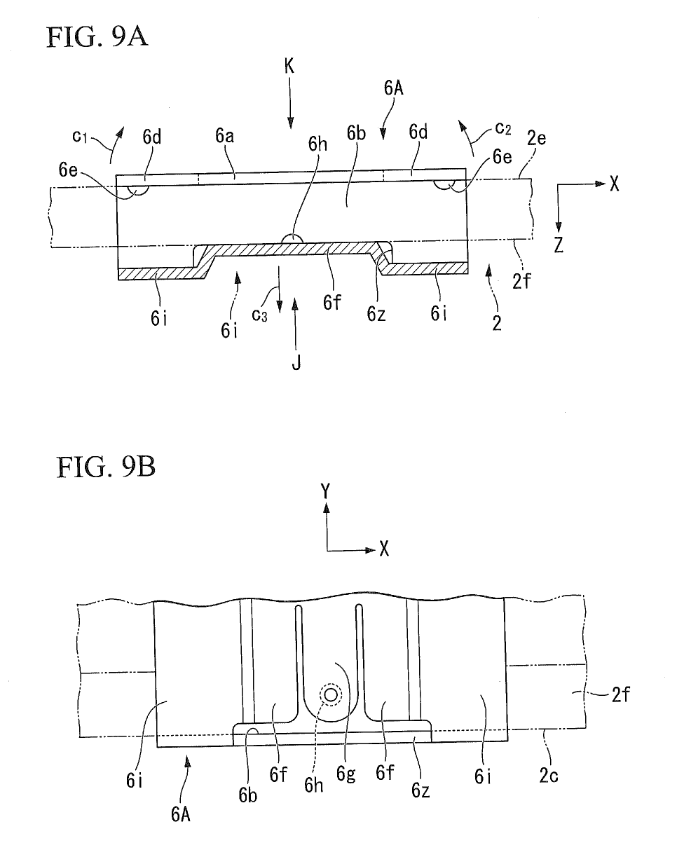

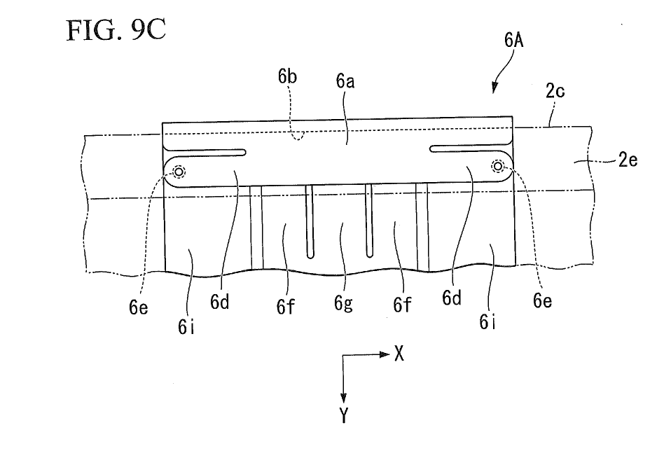

FIG. 1 is a schematic perspective assembly diagram that shows the fixing structure for a display panel according to the exemplary embodiment of the present invention. FIG. 2A is a partial enlarged view of portion A in FIG. 1. FIG. 2B is a partial enlarged diagram from view B in FIG. 1. FIG. 3 is a schematic exploded perspective diagram that shows the constitution of a first chassis member and a second chassis member that are used for the fixing structure for a display panel according to the exemplary embodiment of the present invention. FIG. 4A is a cross-sectional diagram taken along C₁-C₁ in FIG. 3. FIG. 4B is a diagram from view C₂ in FIG. 3. FIG. 5A is a cross-sectional diagram taken along D-D in FIG. 3. FIG. 5B is a cross-sectional diagram taken along F-F in FIG. 5A. FIG. 6 is a schematic exploded perspective diagram that shows the constitution of a first coupling fixing portion of a fixing chassis used for the fixing structure for a display panel according to the exemplary embodiment of the present invention. FIG. 7 is a schematic exploded perspective view that shows the constitution of a coupled body of the fixing chassis and a third chassis member used in the fixing structure for a display panel according to the exemplary embodiment of the present invention. FIG. 8 is a diagram from view G in FIG. 7. FIG. 9A is a cross-sectional diagram taken along H-H in FIG. 7. FIG. 9B is a diagram from view J in FIG. 9A. FIG. 9C is a diagram from view K in FIG. 9A.

A liquid crystal panel assembly 1 that has a fixing structure for a display panel of the present exemplary embodiment shall be described.

The liquid crystal panel assembly 1 is an assembly in which a liquid crystal panel 2 having a rectangular plate shape (display panel) is fixed by a fixing chassis 3, as shown in FIG. 1, FIG. 2A, and FIG. 2B.

First, the shape of the liquid crystal panel 2 that is fixed by the fixing chassis 3 shall be described.

As the liquid crystal panel 2, it is possible to adopt one with of a suitable screen size, provided it has a rectangular plate shape. FIG. 1 shows a constitution with a rectangular plate shape that is horizontally long that is used for liquid crystal televisions.

Hereinbelow, in order to simplify the description, in the liquid crystal panel 2 and the liquid crystal panel assembly 1, the axis that extends in the horizontal direction of the screen of a rectangular image display portion 2g that performs image display (refer to FIG. 2B) shall be denoted as the X axis, the axis that extends in the vertical direction that is perpendicular with that shall be denoted as the Y axis, and the axis that is perpendicular with the X axis and Y axis and that extends from the front surface side toward the back surface side of the image display portion 2g shall be denoted as the Z axis, and directions shall be expressed referring to the X axis, the Y axis and the Z axis. The positive direction of the X axis is the direction advancing from right to left when viewing the Y axis aligned with the vertical axis and the Z axis from the negative direction to the positive direction. The positive direction of the Y axis is, when the Y axis is aligned with the vertical axis, the direction advancing from vertically downward to vertically upward. The positive direction of the Z axis is the direction from the front surface side to the back surface side of the image display portion 2. The Z axis direction agrees with the plate thickness direction of the liquid crystal panel 2.

The directions of the X axis, Y axis and Z axis correspond to the directions of the X axis, Y axis and Z axis noted in the figures.

The liquid crystal panel 2 includes an upper side surface 2a, a right side surface 2b, a lower side surface 2c, and a left side surface 2d, as planar side surfaces on the outer periphery forming a rectangular outer shape. The upper side surface 2a and the lower side surface 2c are side surfaces along the long direction (X-axis direction) of the liquid crystal panel 2, and are mutually opposed in the short direction (Y-axis direction). The right side surface 2b and the left side surface 2d are side surfaces along the Y-axis direction, and are mutually opposed in the X-axis direction. That is to say, in the rectangular contour of the liquid crystal panel 2, the upper side surface 2a and the lower side surface 2c are mutually opposing sides in the Y-axis direction, and the right side surface 2b and the left side surface 2d are mutually opposing sides in the X axis direction.

A round surface (R surface) may be respectively provided between the upper side surface 2a and the right side surface 2b, between the right side surface 2b and the lower side surface 2c, between the lower side surface 2c and the left side surface 2d, and between the left side surface 2d and the upper side surface 2a, connecting these side surfaces in a rounded manner with a cylindrical shape.

A front side fixing surface 2e that is a planar portion with a rectangular frame shape that encloses the periphery of the image display portion 2g is provided on the Z-axis negative direction side in the plate thickness direction (Z-axis direction) of the liquid crystal panel 2. The outer periphery portion of the front side fixing surface 2e is connected to the upper side surface 2a, the right side surface 2b, the lower side surface 2c, and the left side surface 2d.

A rear side fixing surface 2f that is a planar portion with a rectangular frame shape that is parallel with the front side fixing surface 2e at a position facing the front side fixing surface 2e along at least the right side surface 2b, the lower side surface 2c, and the left side surface 2d, as shown in FIG. 3, is provided on the Z-axis positive direction side in the thickness direction of the liquid crystal panel 2. The outer periphery portion of the rear side fixing surface 2f is connected to the right side surface 2b, the lower side surface 2c, and the left side surface 2d.

In this way, in the present exemplary embodiment, the distance between the front side fixing surface 2e and the rear side fixing surface 2f is constant.

With this kind of constitution, corner portions 2A, 2B, 2C, and 2D are formed by the side surfaces of the outer periphery side portions of the liquid crystal panel 2 at the regions of the four corners of the rectangular contour of the liquid crystal panel 2.

The corner portion 2A (first corner portion) has an outer shape that is formed by the upper side surface 2a, the left side surface 2d, the front side fixing surface 2e, and the rear side fixing surface 2f. The corner portion 2B (second corner portion) is a corner portion that is adjacent to the corner portion 2A in the X-axis direction, and its outer shape is formed by the upper side surface 2a, the right side surface 2b, the front side fixing surface 2e, and the rear side fixing surface 2f.

The corner portions 2C and 2D are corner portions that are adjacent to the corner portions 2B and 2A, respectively, in the Y-axis direction. The region of the outer periphery portion of the liquid crystal panel 2 that is sandwiched between the corner portions 2C and 2D is called a middle portion 2E. That is to say, the middle portion 2E has an outer shape that is formed by the lower side surface 2c, the front side fixing surface 2e, and the rear side fixing surface 2f.

In the present exemplary embodiment, since the upper side surface 2a, the right side surface 2b, the lower side surface 2c and the left side surface 2d respectively consist of flat surfaces, although there is no clear boundary line between the corner portions 2A, 2B, 2C, and 2D, they are defined as mutually non-overlapping regions. Accordingly, the lengths of the corner portions 2A, 2B, 2C, and 2D along the X-axis direction and the Y-axis direction are all shorter than half the width in the short direction of the rectangular contour of the liquid crystal panel 2 (width in the Y-axis direction).

The outline framework of a fixing chassis 3 includes a first chassis member 5, a second chassis member 4, and a third chassis member 6.

As for the fixing chassis 3, in the liquid crystal panel assembly 1, one end side of the first chassis member 5 is secured to the corner portion 2A, one end side of the second chassis member 4 is secured to the corner portion 2B, and one end side of the third chassis member 6 is secured to the middle portion 2E between the corner portions 2C and 2D.

In the present exemplary embodiment, the third chassis member 6 that is secured to the middle portion 2E is secured within a range of approximately one-third of the length of the liquid crystal panel 2 in the X-axis direction, in the center portion of the X-axis direction of the liquid crystal panel 2.

In this kind of state, the other end sides of the first chassis member 5, the second chassis member 4, and the third chassis member 6 are respectively arranged at positions in the center portion of the back surface side of the liquid crystal panel 2 (the Z-axis positive direction side), and mutually coupled. Thereby, the fixing chassis 3 is coupled in a Y-shape seen from the back surface side (the Z-axis positive direction side) of the liquid crystal panel 2.

The first chassis member 5 is a member that is formed by press working a metal plate.

The first chassis member 5 includes: a securing portion 5A (first corner securing portion) that is formed in a channel shape that can enclose the front side fixing surface 2e, the left side surface 2d, and the rear side fixing surface 2f at the corner portion 2A; a long and narrow arm portion 5B of which one end side is connected to the securing portion 5A and that is extended in an oblique direction (hereinbelow called the long direction L_{5B}) from the securing portion 5A at the back surface side of the liquid crystal panel 2; and a coupling portion 5C with an approximately plate shape that is connected to the other end side of the arm portion 5B.

The arm portion 5B has a plate-like portion 5x that is narrowly extended along the long direction L_{5B} and that is comprised by a planar surface that is parallel with the XY plane, and a drawn portion 5y that is formed along the long direction L_{5B} in the center of this plate-like portion 5x in the short direction. In the present embodiment, the drawn portion 5y is provided in a concave shape that is concave from the Z-axis positive direction to the negative direction side in the liquid crystal panel assembly 1.

The long direction L_{5B} of the arm portion 5B extends in the direction toward the center side of the liquid crystal panel 2 in the XY plane, when a left-side surface securing portion 5b of the securing portion 5A described below is secured on the left-side surface 2d of the corner portion 2A, as shown in FIG. 1. That is to say, as it heads from the one end side to the other end side of the arm portion 5B, it extends toward the X-axis negative direction side and the Y-axis negative direction side.

The securing portion 5A is for securing from the X-axis positive direction side and the Y-axis positive direction side to the corner portion 2A of the liquid crystal panel 2, and as shown in FIGS. 2A and 2B, includes a left-side surface securing portion 5b, a front side pressing portion 5a, a plate-like portion 5i, a rear-side pressing portion 5f, and an upper-side surface securing portion 5c.

The left-side surface securing portion 5b is a long and narrow, rectangular planar portion that constitutes the groove bottom of the channel-shaped securing portion 5A, and its width in the short direction is formed wider than the width in the Z-axis direction of the left-side surface 2d so as to be able to abut and secure to the left side surface 2d along the long direction.

The front side pressing portion 5a is a planar portion that constitutes one groove side surface of the channel-shaped securing portion 5A, and is formed bent back perpendicularly from one end portion of the left-side surface securing portion 5b in the short direction (the end portion on the left side in the illustration of FIG. 4A), so as to overlap with the front side fixing surface 2e when the left-side surface securing portion 5b is secured on the left-side surface 2d of the corner portion 2A.

In the present exemplary embodiment, as shown in FIG. 2B, a slit that extends in the long direction of the left-side surface securing portion 5b is provided at both end portions of the bent tip side of the front side pressing portion 5a, and thereby a pair of flat spring portions 5d that are formed in a flake shape having a width that is narrower than the width of the front side fixing surface 2e in the X-axis direction at the corner portion 2A, and extended along the long direction of the left-side surface securing portion 5b, are formed.

As shown in FIG. 4A, a hemispherical portion 5e that is projected in a hemispheric shape toward the plate-like portion 5i that constitutes the other groove side surface of the channel-shaped securing portion 5A is provided at the distal end portion of each flat spring portion 5d. The hemispherical portion 5e is formed integrally with the flat spring portion 5d by a drawing process.

In the natural state in which no external force is applied, each flat spring portion 5d is aligned on the same plane with the front side pressing portion 5a, but when an external force acts, it can undergo flexural deformation in an out-of-plane direction of the front side pressing portion 5a, for example in a direction moving away from the plate-like portion 5i as shown by the arrows a₁ and a₂ in FIG. 4A.

The plate-like portion 5i, as shown in FIGS. 2A and 4A, is formed bent back at a right angle to the same direction side as the front side pressing portion 5a from the other end portion of the left-side surface securing portion 5b in the short direction (the end portion of the illustrated right side in FIG. 4A) so as to overlap with the rear side fixing surface 2f when the left-side surface securing portion 5b is secured on the left side surface 2d of the corner portion 2A.

However, at the plate-like portion 5i, a drawing process that produces a concavity toward the front side pressing portion 5a side is performed at a position opposite the front side pressing portion 5a at the middle portion in the long direction of the left-side surface securing portion 5b, and the rear side pressing portion 5f, which is a planar portion that is parallel with the plate-like portion 5i, is formed.

As shown in FIG. 4A, the gap between the rear-side pressing portion 5f and the front side pressing portion 5a is set to a dimension slightly wider than the distance between the front side fixing surface 2e and the rear side fixing surface 2f, so as to be able to insert the corner portion 2A in this gap.

Also, as shown in FIG. 2A, the rear-side pressing portion 5f and the left-side surface securing portion 5b are separated via an escape hole 5z. At the end portion of the rear-side pressing portion 5f that faces the escape hole 5z, two slits are formed extending in the direction of the normal of the left-side surface securing portion 5b (the direction of the X axis of FIG. 2A), and a projecting piece-shaped flat spring portion 5g that is extended along the normal direction of the left-side surface securing portion 5b is formed between these two slits.

In the natural state in which no external force is applied, the flat spring portion 5g is aligned on the same plane with the rear-side pressing portion 5f, but when an external force acts, it can undergo flexural deformation in an out-of-plane direction of the rear-side pressing portion 5f, for example in a direction moving away from the front side pressing portion 5a as shown by the arrow a₃ in FIG. 4B.

At the distal end portion of the flat spring portion 5g, a hemispherical portion 5h that is projected in a hemispheric shape toward the front side pressing portion 5a is provided. The hemispherical portion 5h is formed integrally with the flat spring portion 5g by a drawing process.

The projection amount of the hemispherical portions 5e and 5h from the flat spring portions 5d and 5g is set to a projection amount such that, when the corner portion 2A is inserted in the groove width that is formed by the front side pressing portion 5a and the rear-side pressing portion 5f, the hemispherical portions 5e and 5h reliably abut the front side fixing surface 2e and the rear side fixing surface 2f, respectively, and can press the front side fixing surface 2e and the rear side fixing surface 2f.

In the present exemplary embodiment, the plate-like portion 5i and the rear side pressing surface 5f are smoothly connected with the plate-like portion 5x and the drawn portion 5y of the arm portion 5B, respectively, at the end portion on the opposite side of the left-side surface securing portion 5b.

The upper-side surface securing portion 5c is a flat plate portion that is bent back perpendicularly from the end portion of the plate-like portion 5i positioned on the Y-axis positive direction side toward the front side pressing portion 5a, so as to secure onto the upper side surface 2a, when the left-side surface securing portion 5b of the securing portion 5A is secured to the left side surface 2d of the corner portion 2A.

The coupling portion 5C serves to couple with the other end portions of the second chassis member 4 and the third chassis member 6, and as shown in FIG. 3 includes a fixing portion 5j that extends along a direction parallel with the long direction of the left-side surface securing portion 5b (the Y-axis direction of FIG. 3) at the other end of the arm portion 5B, and projecting piece portions 5k, 5m that are projected in a direction perpendicular with the extension direction of the fixing portion 5j and toward the opposite side of the arm portion 5B, at both end portions in the extension direction of the fixing portion 5j (the Y-axis direction in the drawing).

In the present exemplary embodiment, the fixing portion 5j and the projecting piece portions 5k, 5m includes planar portions that are aligned on the same plane as the plate-like portion 5x of the arm portion 5B.

The projecting piece portion 5k is provided at the end portion of the base end side in the extension direction of the fixing portion 5j (the Y-axis positive direction side of FIG. 3), and as shown in FIG. 6, an oval sliding hole 5p that is long along the projection direction is provided at the distal end portion in the projection direction.

The projecting piece portion 5m is provided at the end portion of the distal end side in the extension direction of the fixing portion 5j (the Y-axis negative direction side of FIG. 3), and as shown in FIG. 6, a sliding hole 5q that has the same shape as the sliding hole 5p is provided at the distal end portion in the projection direction.

The sliding holes 5p and 5q are through holes that, by inserting a fixing screw 7 therethrough, are screw fastened with the coupling portion 4C of the second chassis member 4 described below, and thereby position and couple the coupling portion 5C in the Y-axis direction of the liquid crystal panel 2. For this reason, the short diameter of the sliding holes 5p and 5q has a size that allows insertion of the fixing screw 7 without looseness.

As shown in FIG. 3, a rectangular hole 5r for insertion of a projecting piece portion 6r of the third chassis member 6 described below, and a female screw portion 5s for screw fastening the third chassis member 6 are provided at the base end side of the projecting piece portion 5k in the projection direction.

Two cut and bent portions 5n that are arranged in a straight line along the extension direction of the fixing portion 5j and projected outward above the fixing portion 5j are provided in the fixing portion 5j at positions nearer to the projecting piece portion 5m for insertion into slits 6m of the third chassis member 6 described below.

The second chassis member 4 is a member that has formed by press working a metal plate.

The second chassis member 4 includes: a securing portion 4A (second corner securing portion) that is formed in a channel shape that can enclose the front side fixing surface 2e, the right side surface 2b, and the rear side fixing surface 2f at the corner portion 2B, a long and narrow arm portion 4B of which one end side is connected to the securing portion 4A and that is extended in an oblique direction (hereinbelow called the long direction L_{4B}) from the securing portion 4A; and a coupling portion 4C with an approximate plate shape that is connected to the other end side of the arm portion 4B. The arm portion 4B has a plate-like portion 4x that is narrowly extended along the long direction L_{4B} and that is comprised by a planar surface that is parallel with the XY plane, and a drawn portion 4y that is formed along the long direction L_{4B} in the center of this plate-like portion 4x in the short direction. The drawn portion 4y is provided in a concave shape that is concave from the Z-axis positive direction to the negative direction side in the liquid crystal panel assembly 1.

The second chassis member 4 is a member that, when secured to the corner portion 2B, and with a plane that is parallel with the XZ plane serving as a plane of symmetry, is formed in a plane symmetrical shape, except for some potions, with the first chassis member 5 that is secured with the corner portion 2A, and arranged in a plane symmetrical positional relation except for some portions.

Therefore, at the second chassis member 4, the same alphabetic notation as in the first chassis member 5 is given to the reference symbols of the corresponding portions that are provided in shapes and positional relations that are plane symmetrical with the first chassis member 5. Hereinbelow, a simple description shall be given centering on the points differing with the first chassis member 5.

The securing portion 4A is for securing from the X-axis negative direction side and the Y-axis positive direction side to the corner portion 2B of the liquid crystal panel 2, and as shown in FIGS. 5A, 5B, and 5C, includes a right-side surface securing portion 4b, a front side pressing portion 4a, a plate-like portion 4i, a rear-side pressing portion 4f, and an upper-side surface securing portion 4c respectively corresponding to the left-side surface securing portion 5b, the front side pressing portion 5a, the plate-like portion 5i, the rear-side pressing portion 5f, and the upper-side surface securing portion 5c of the first chassis member 5.

The right-side surface securing portion 4b has a shape that is plane symmetrical with the left-side surface securing portion 5b, and is provided so as to be able to abut and secure to the right side surface 2b.

The front side pressing portion 4a has a shape that is plane symmetrical with the front side pressing portion 5a. For this reason, it has a flat spring portion 4d and a hemispherical portion 4e that are provided in a plane symmetrical manner, corresponding to the flat spring portion 5d and the hemispherical portion 5e, and is provided so as to overlap with the front side fixing surface 2e of the corner portion 2B.

The plate-like portion 4i has a shape that is plane symmetrical with the plate-like portion 5i, and is provided so as to overlap with the rear side fixing surface 2f when the right-side surface securing portion 4b is secured on the right side surface 2b of the corner portion 2B.

The rear-side pressing portion 4f has a shape that is plane symmetrical with the rear-side pressing portion 5f. For this reason, the rear-side pressing portion 4f and the right-side surface securing portion 4b are separated via an escape hole 4z that corresponds to the escape hole 5z. Also, the rear-side pressing portion 4f includes a flat spring portion 4g and a hemispherical portion 4h that are provided in a plane symmetrical manner, corresponding to the plate spring portion 5g and the hemispherical portion 5h.

The hemispherical portions 4e and 4h of the flat spring portions 4d and 4g are provided so that, upon receiving an external force from the front side fixing surface 2e and the rear side fixing surface 2f, respectively, they undergo flexural deformation in the direction of the arrows b₁ (b₂), and b₃ that are out-of-plane directions of the front side fixing surface 2e and the rear side fixing surface 2f, and abut the front side fixing surface 2e and the rear side fixing surface 2f while biasing a resiliency force when the right-side surface securing portion 4b is secured on the right side surface 2b of the corner portion 2B, as shown in FIG. 5A.

The plate like portion 4i and the rear side fixing surface 4f are smoothly connected with the plate-like portion 4x and the drawn portion 4y of the arm portion 4B. The arm portion 4B is formed in a shape that is plane symmetrical with the arm portion 5B, and is arranged in a positional relation that is plane symmetrical with the arm portion 5B.

The upper-side surface securing portion 4c has a shape that is plane symmetrical with the upper-side surface securing portion 5c, and is arranged in a positional relation that is plane symmetrical with the upper-side surface securing portion 5c.

As shown in FIG. 3, the coupling portion 4C includes a fixing portion 4j, a rectangular hole 4r, a female screw portion 4s, and cut and bent portions 4n that respectively have shapes that are plane symmetrical with the fixing portion 5j the rectangular hole 5r, the female screw portion 5s, and the cut and bent portions 5n of the coupling portion 5C and are arranged in a plane symmetrical positional relation with them.

Also, the coupling portion 4C includes projecting piece portions 4K, 4M that correspond with the projecting piece portions 5k, 5m of the coupling portion 5C.

The projecting piece portion 4K is provided at the end portion of the base end side in the extension direction of the fixing portion 4j (the Y-axis positive direction side of FIG. 3), and as shown in FIG. 6, includes at the distal end portion in the projection direction a fixing surface 4t that is formed in a bent in a stepped manner.

The fixing surface 4t is provided so as to overlap in the Z-axis direction the distal end portion of the projecting piece portion 5k by going under it on the Z-axis negative direction side when the first chassis member 5 and the second chassis member 4 are secured on the corner portion 2A and the corner portion 2B, respectively.

At the center portion of the fixing surface 4t, a female screw portion 4v is provided that threads with the fixing screw 7 at a position that overlaps with the sliding hole 5p of the projecting piece portion 5k, when overlapped in this way. The distance from the upper-side surface securing portion 4c and the right-side surface securing portion 4b to the center position of the female screw portion 4v, and the distance from the upper-side surface securing portion 5c and the left-side surface securing portion 5b to the center position of the sliding hole 5p are set to be the same.

The projecting piece portion 4M is provided at the end portion of the distal end side in the extension direction of the fixing portion 4j (the Y-axis negative direction side of FIG. 3), and as shown in FIG. 6, includes at the distal end portion in the projection direction a fixing surface 4u that is formed in the same manner as the fixing surface 4t.

At the center portion of the fixing surface 4u, similarly to the fixing surface 4t, a female screw portion 4w is provided that threads with the fixing screw 7 at a position that overlaps with the sliding hole 5q of the projecting piece portion 5m. The distance from the upper-side surface securing portion 4c and the right-side surface securing portion 4b to the center position of the female screw portion 4v, and the distance from the upper-side surface securing portion 5c and the left-side surface securing portion 5b to the center position of the sliding hole 5q are set to be the same.

The third chassis member 6 is a member that is formed by press working a metal plate.

The third chassis member 6, as shown in FIGS. 1, 7, and 8, includes: two securing portions 6A (opposing side securing portions) that are formed in a channel shape to be able enclose the front side fixing surface 2e , the lower side surface 2c, and the rear side fixing surface 2f at the middle portion 2E; arm portions 6B, 6D of which one end side is respectively connected to the securing portions 6A; and a coupling portion 6C that is fixed to the other end side of the arm portions 6B, 6D.

The arm portions 6B, 6D in common have a plate-like portion 6x that is narrowly extended along the long direction L_{6B} from each securing portion 6A and a drawn portion 6y that is formed along the long direction L₆ in the center of this plate-like portion 6x in the short direction thereof. In the present exemplary embodiment, the long direction L₆ is the normal direction of a lower-side surface securing portion 6b of the securing portion 6A described below.

The securing portion 6A secures to the middle portion 2E of the liquid crystal panel 2 from the Y-axis negative direction side, and has the same shape as the securing portion 5A with the upper-side surface securing portion 5c removed. That is to say, as shown in FIG. 9A, it includes lower-side surface securing portion 6b, a front side pressing portion 6a, a plate-like portion 6i, and a rear-side pressing portion 6f corresponding to the left-side surface securing portion 5b, the front side pressing portion 5a, the plate-like portion 5i, and the rear-side pressing portion 5f of the securing portion 5A. Hereinbelow, a description shall be given centered on the points of difference with the engaging portion 5A.

The lower-side surface securing portion 6b is a long and narrow, rectangular planar portion that constitutes the groove bottom of the channel-shaped securing portion 6A, and its width in the short direction is formed wider than the width in the Z-axis direction of the lower side surface 2.

The front side pressing portion 6a is a planar portion that constitutes one groove side surface of the channel-shaped securing portion 6A, and is formed bent back perpendicularly from one end portion of the lower-side surface securing portion 6b in the short direction (the end portion on the upper side in the illustration of FIG. 9A), so as to overlap with the front side fixing surface 2e when the lower-side surface securing portion 6b is secured on the lower side surface 2c of the middle portion 2E.

In the present exemplary embodiment, as shown in FIG. 9C, a slit that extends in the long direction of the lower-side surface securing portion 6b is provided at both end portions of the bent tip side of the front side pressing portion 6a, and thereby a pair of flat spring portions 6d that are formed in a flake shape having a width that is narrower than the width of the front side fixing surface 2e at the middle portion 2E in the Z-axis direction, and extended along the long direction of the lower-side surface securing portion 6b are formed.

As shown in FIG. 9A, a hemispherical portion 6e that is projected in a hemispheric shape toward the plate-like portion 6i that constitutes the other groove side surface of the channel-shaped securing portion 6A is provided at the distal end portion of each flat spring portion 6d. The hemispherical portion 6e is formed integrally with the flat spring portion 6d by a drawing process.

Each flat spring portion 6d can undergo flexural deformation in an out-of-plane direction of the front side pressing portion 6a, for example in a direction moving away from the plate-like portion 6i as shown by the arrows c₁ and c₂ in FIG. 9A.

The plate-like portion 6i, as shown in FIGS. 9A, is formed bent back at a right angle to the same direction side as the front side pressing portion 6a from the other end portion of the lower-side surface securing portion 6b in the short direction (the end portion of the lower side in the illustration of FIG. 9A) so as to overlap with the rear side fixing surface 2f when the lower-side surface securing portion 6b is secured on the lower side surface 2c of the middle portion 2E.

However, at the plate-like portion 6i, a drawing process that produces a concavity toward the front side pressing portion 6a is performed at a position opposite the front side pressing portion 6a at the middle portion of the lower-side surface securing portion 6b in the long direction, and the rear side pressing portion 6f, which is a planar portion that is parallel with the plate-like portion 6i, is formed.

As shown in FIG. 9A, the gap between the rear-side pressing portion 6f and the front side pressing portion 6a is set to a dimension slightly wider than the distance between the front side fixing surface 2e and the rear side fixing surface 2f, so as to be able to insert the middle portion 2E in this gap.

Also, as shown in FIG. 9B, the rear-side pressing portion 6f and the lower-side surface securing portion 6b are separated via an escape hole 6z. At the end portion of the rear-side pressing portion 6f that faces the escape hole 6z, two slits are formed extending in the direction of the normal of the lower-side surface securing portion 6b (the direction of the Y axis of FIGS. 8 and 9B), and a projecting piece-shaped flat spring portion 6g that is extended along the nolinal direction of the lower-side surface securing portion 6b is formed between these two slits.

At the distal end portion of the flat spring portion 6g, a hemispherical portion 6h that is projected in a hemispheric shape toward the front side pressing portion 6a is provided. The hemispherical portion 6h is formed integrally with the flat spring portion 6g by a drawing process.

The flat spring portion 6g can undergo flexural deformation in an out-of-plane direction of the rear-side pressing portion 6f, for example, in a direction moving away from the front side pressing portion 6a as shown by the arrow c₃ in FIG. 9A.

The projection amount of the hemispherical portions 6e and 6h from the flat spring portions 6d and 6g is set to a projection amount such that, when the middle portion 2E is inserted in the groove width that is formed by the front side pressing portion 6a and the rear-side pressing portion 6f, the hemispherical portions 6e and 6h reliably abut the front side fixing surface 2e and the rear side fixing surface 2f, respectively, and can press the front side fixing surface 2e and the rear side fixing surface 2f.

In the present exemplary embodiment, the plate-like portion 6i and the rear side pressing portion 6f are smoothly connected with the plate-like portion 6x and the drawn portion 6y of the arm portions 6B and 6D, respectively, at the end portion on the opposite side of the lower-side surface securing portion 6b.

In the present exemplary embodiment, the long direction L_{b} of the arm portions 6B and 6D agrees with the normal direction of the lower-side surface securing portion 6b.

The coupling portion 6C, as shown in FIGS. 7 and 8, includes: a coupling portion main body 6s with an approximate cuboid shape that is connected with the plate-like portion 6x at the end portion on the opposite side of the securing portion 6A in the long direction L₆ of the arm portions 6B and 6D; a pair of projecting piece portions 6r that are projected laterally from the side surface of the coupling portion main body 6s opposite the side to which the arm portions 6B and 6D are connected; and fixing flange portions 6j, 6k that are projected laterally from each of the opposing side surfaces of the coupling portion main body 6s sandwiching the side surface from which the projecting piece portions 6r are projected.

The fixing flange portion 6j is a flat plate portion for being fixed in an overlapping manner to the fixing portion 4j of the coupling portion 4C, and as shown in FIG. 1, in the state of each securing portion 6A being secured to the middle portion 2E, it is extended from the end portion of the coupling portion main body 6s on the Z-axis negative direction side to the X-axis negative side direction across the long direction of the fixing portion 4j.

In the fixing flange portion 6j is provided a sliding hole 6p that, as shown in HG. 8, has an opening shape that exposes the female screw portion 4s in the state of each securing portion 6A being secured to the middle portion 2E, and that is long along the Y-axis direction. Also, in the fixing flange portion 6j are provided a pair of slits 6m having the shape of long and narrow rectangular holes in the Y-axis direction into which the pair of cut and bent portions 4n can be inserted in the state of each securing portion 6A being secured to the middle portion 2E.

The fixing flange portion 6k is a flat plate portion for being fixed in an overlapping manner to the fixing portion 5j of the coupling portion 5C, and as shown in FIG. 1, in the state of each securing portion 6A being secured to the middle portion 2E, it is extended from the end portion of the coupling portion main body 6s on the Z-axis negative direction side to the X-axis positive direction side across the long direction of the fixing portion 5j.

In the fixing flange portion 6k is provided an oblong sliding hole 6q that, as shown in FIG. 8, has an opening shape that exposes the female screw portion 5s in the state of each securing portion 6A being secured to the middle portion 2E, and that is long along the Y-axis direction. Also, in the fixing flange portion 6k are provided a pair of slits 6n having the shape of long and narrow rectangular holes in the Y-axis direction into which the pair of cut and bent portions 5n can be inserted in the state of each securing portion 6A being secured to the middle portion 2E.

In the state of each securing portion 6A being secured to the middle portion 2E, and the fixing flange portions 6j and 6k being overlapped on the fixing portions 4j and 5j, respectively, the projecting piece portions 6r are provided to be capable of being inserted in the rectangular hole 4r of the coupling portion 4C and the rectangular hole 5r of the coupling portion 5C from the Z-axis positive direction side and the Y-axis negative direction side. In the present exemplary embodiment, they each have a rectangular shape that is projected to the Y-axis positive direction side from a position shifted to the Z-axis negative direction side by the plate thickness amount of the fixing portions 4j and 5j from the positions of the fixing flange portions 6j, 6k in the Z-axis direction.

For this reason, in the liquid crystal assembly 1, the projecting piece portions 6r are inserted in the openings of the rectangular holes 4r and 5r, respectively, from the Z-axis positive direction side toward the Y-axis positive direction side, and by diving under to the Z-axis negative direction side of the fixing portions 4j and 5j, are inserted so as to overlap the fixing portions 4j, 5j.

This kind of fixing chassis 3 is coupled by the fixing screws 7 at the projecting piece portions 5k, 4K and the projecting piece portions 5m and 4M, in the state of the securing portions 5A, 4A being secured to the corner portions 2A, 2B as shown in FIG. 7. Also, it is coupled by the fixing screws 7 at the fixing portion 4j, the fixing flange portion 6j, and the fixing portion 5j and the fixing flange portion 6k, respectively, in the state of each securing portion 6A being secured to the middle portion 2E.

Here, the left-side surface securing portion 5b and the right-side surface securing portion 4b are respectively secured to the left side surface 2d and the right side surface 2b without looseness, and the upper-side surface securing portions 5c, 4c are secured to the upper side surface 2a of the corner portions 2A, 2B without looseness.

For this reason, with regard to the fixing chassis 3 in the liquid crystal assembly 1, the liquid crystal panel 2 is fixed without looseness to the fixing chassis 3 in the X-axis direction and the Y-axis direction.

Next, a method of fixing a display panel of the present exemplary embodiment that fixes the liquid crystal panel 2 by the fixing chassis 3 described above shall be described.

The present fixing method is a fixing method that forms the liquid crystal panel assembly 1 in accordance with the fixing structure for a display panel of the present exemplary embodiment, by performing the first to fourth steps described hereinbelow.

The first step is a step that secures the first chassis member 5 to the corner portion 2A of the liquid crystal panel 2, and secures the first chassis member 5 to the corner portion 2B of the liquid crystal panel 2 that is next to the corner portion 2A.

The order of securing the first chassis member 5 and the second chassis member 4 is not particularly limited. After first securing either one of the first chassis member 5 and the second chassis member 4, the other may be secured, or the first chassis member 5 and the second chassis member 4 may be secured simultaneously. Hereinbelow, a description shall be given with the example of first securing the second chassis member 4, and then securing the first chassis member 5.

First, as shown in FIG. 3, the upper-side surface securing portion 4c of the second chassis member 4 is oriented to the Y-axis positive direction side, and the long direction of the right-side surface securing portion 4b is arranged so as to follow the Y-axis direction. Then, the second chassis member 4 is moved from the Y-axis positive direction side toward the negative direction side, and the end portion of the right side surface 2b side of the corner portion 2B is inserted in the groove of the securing portion 4A. As shown in FIG. 5A, the groove width formed by the front-side pressing portion 4a and the rear-side pressing portion 4f of the securing portion 4A is slightly wider than the width of the securing portion 4A in the Z-axis direction , even at the interval between the plate surfaces of the flat spring portions 4d, 4g that are aligned at the front-side pressing portion 4a and the rear-side pressing portion 4f in a natural state, it is possible to easily perform insertion.

When the insertion proceeds, and the front side fixing surface 2e and the rear side fixing surface 2f of the corner portion 2B abut the hemispherical portions 4e, 4h, since the flat spring portions 4d, 4g undergo flexural deformation in the direction of the arrows b₁, b₂, b₃ of FIG. 5A, it is possible to continue insertion to the corner portion 2B.

By doing so in this way, as shown in FIG. 7, it is possible to secure the right-side surface securing portion 4b and the upper-side surface securing portion 4c of the securing portion 4A to the right side surface 2b and the upper side surface 2a of the corner portion 2B, respectively. At this time, the arm portion 4B is arranged in a state of being extended in an oblique direction from the corner portion 2B to the center side of the liquid crystal panel 2 at the back surface of the liquid crystal panel 2.

Also, in this securing state, due to the flexural deformation of the flat spring portions 4d, 4g, the corner portion 2B receives an action of resilient force to the Z-axis negative direction side and the Z-axis positive direction side from the hemispherical portions 4e, 4h, respectively. That is, the corner portion 2B is sandwiched by the flat spring portions 4d, 4g of the securing portion 4A in a state of the resilient force acting in the Z-axis direction, which is the plate thickness direction of the liquid crystal panel 2. For this reason, the corner portion 2B is also secured in the plate thickness direction by the securing portion 4A.

In this way, the flat spring portions 4d, 4g constitute a second resilient sandwiching portion that sandwiches the liquid crystal panel 2 by causing a resilient force to act in the plate thickness direction of the liquid crystal panel 2 at the corner portion 2B.

Next, as shown in FIG. 3, in the same way, the first chassis member 5 is secured to the corner portion 2A. The operation of this securing process is readily understood from the description of the securing process of the aforementioned second chassis member 4, since the securing portion 5A of the first chassis member 5 has a shape that is plane symmetrical with the engaging portion 4A of the second chassis member 4. For this reason, a detailed description shall be omitted.

Thereby, as shown in FIG. 7, it is possible to secure the left-side surface securing portion 5b and the upper-side surface securing portion 5c of the securing portion 5A to the left side surface 2d and the upper side surface 2a of the corner portion 2A, respectively. At this time, the arm portion 5B is arranged in a state of being extended in an oblique direction from the corner portion 2A toward the center side of the liquid crystal panel 2 at the back surface of the liquid crystal panel 2.

Also, in this securing state, due to the flexural deformation of the flat spring portions 5d, 5g, the corner portion 2A receives an action of resilient force to the Z-axis negative direction side and the Z-axis positive direction side from the hemispherical portions 5e, 5h, respectively. That is, the corner portion 2A is sandwiched by the flat spring portions 5d, 5g at the securing portion 5A in a state of the resilient force acting in the Z-axis direction, which is the plate thickness direction of the liquid crystal panel 2. For this reason, the corner portion 2A is also secured in the plate thickness direction by the securing portion 5A.

In this way, the flat spring portions 5d, 5g constitute a first resilient sandwiching portion that sandwiches the liquid crystal panel 2 by causing a resilient force to act in the plate thickness direction of the liquid crystal panel 2 at the corner portion 2A.

In the present step, since the securing portions 4A, 5A are secured in a state of a resilient force acting in the plate thickness direction, it is possible to maintain the state of the securing portions 4A, 5A being secured to the upper side surface 2a, the right side surface 2b, and the left side surface 2d that are side surfaces of the outer periphery side.

However, since the securing state with the side surfaces of the outer periphery sides can be corrected by adjusting the facing distance in the second step and the fourth step described below, it may be a temporary securing state that differs from the final securing state with respect to the side surface of each outer periphery side. For example, the interval between each of the side surfaces of the outer periphery sides, and the right-side surface securing portion 4b, the left-side surface securing portion 5b and the upper-side surface securing portions 4c, 5c may be in a securing state of uneven abutting, and may be somewhat shifted from the securing position.

With this, the first step is completed.

Next, the second step is performed. The present step, as shown in FIG. 7, is a step that forms a coupled body 8 with the first chassis member 5 and the second chassis member 4 by mutually coupling them at the back surface side of the liquid crystal panel 2, in the state of having secured the first chassis member 5 and the second chassis member 4, which were respectively secured to the liquid crystal panel 2 in the first step, to at least the left side surface 2d and the right side surface 2b that are a mutually opposing pair of side surfaces of the outer periphery sides of the liquid crystal panel 2 by adjusting the mutual opposing distance.

When the first step is completed, the securing portion 4A and the arm portion 4B of the second chassis member 4, and the securing portion 5A and the arm portion 5B of the first chassis member 5 are arranged in a positional relation that is approximately plane symmetrical with a plane that is parallel with the YZ plane, due to their respective symmetry.

At this time, the distal end portions of the projecting piece portions 4K, 4M in the coupling portion 4C and the distal end portions of the projecting piece portions 5k, 5m in the coupling portion 5C are respectively opposed in the X-axis direction.

That is to say, as shown in FIG. 6, the fixing surface 4t (4u) of the projecting piece portion 4K (4M) overlaps the distal end portion of the projecting piece portion 5k (5m) by ducking thereunder in the Z-axis negative direction. Thereby, a positional relation comes about in which the female screw portion 4v (4w) overlaps with the interior of the sliding hole 5p (5q) of the projecting piece portion 5k (5m).

Here, in the case of the female screw portion 4v (4w) not overlapping with the interior of the sliding hole 5p (5q) due to there being a large difference between the securing state of the upper-side surface securing portion 4c and the upper side surface 2c at the corner portion 2B, and the securing state of the upper-side surface securing portion 5c and the upper side surface 2c at the corner portion 2A, the securing portions 4A, 5A are respectively pushed to the liquid crystal panel 2 side from the Y-axis negative direction side.

Next, for example, by pushing the securing portions 4A, 5A from the X-axis negative direction side, positive direction side to the liquid crystal panel 2 side, the opposing distance of the securing portions 4A, 5A in the X-axis direction is adjusted. Thereby, a state is obtained in which at the corner portions 2A and 2B the left-side surface securing portion 5b and the right-side surface securing portion 4b are secured without looseness to the left side surface 2d and the right side surface 2b, respectively.

Since the sliding hole 5p (5q) is provided with an oblong shape having a long diameter in the X-axis direction, in the range of the long diameter dimension of the sliding hole 5p (5q), it is possible to perform positional adjustment in the X-axis direction of the first chassis member 5 and the second chassis member 4.

For this reason, it is possible to secure the securing portions 4A, 5A without looseness in the X-axis direction even if there are variations in the width of the liquid crystal panel 2 in the X-axis direction due to machining errors.

Next, the fixing screw 7 is inserted via the sliding hole 5p (5q), and screwed together with the female screw portion 4v (4w), whereby the projecting piece portion 5k (5m) and the fixing surface 4t (4u) of the projecting piece portion 4K (4M) are screw fastened.

Since the securing portions 4A, 5A sandwich the corner portions 2B, 2A by causing a resilient force to act in the thickness direction, the positional relation of the second chassis member 4 and the first chassis member 5 with respect to the liquid crystal panel 2 is stable. For this reason, it is possible to perform screw fixing while maintaining the securing state that is formed prior to screw fastening without holding the engaging portions 4A, 5A during the screw fastening. Accordingly, the screw fastening becomes easy.

In this manner, as shown in FIG. 7, a coupled body 8 is formed by the first chassis member 5 and the second chassis member 4, and the second step is finished.

In this manner, the projecting piece portions 5k, 5m of the coupling portion 5C of the first chassis member 5, and the projecting piece portions 4K, 4M of the coupling portion 4C of the second chassis member 5 constitute a first coupling fixing portion that forms the coupled body 8 with the first chassis member 5 and the second chassis member 4, by changing the opposing distance of the corner portions 2B, 2A, and mutually coupling the first chassis member 5 and the second chassis member 4 at the back surface side of the liquid crystal panel 2.

The sliding holes 5p, 5q that are provided in the projecting piece portions 5k, 5m are provided in a mutually parallel manner, along the projection direction of the projecting piece portions 5k, 5m. For this reason, they constitutes a first displacement guidance mechanism that guides the relative displacement of the second chassis member 4 and the first chassis member 5 in mutually opposed directions, that is to say, in the X-axis direction, in the state of the fixing screw 7 being inserted in each.

Since the present exemplary embodiment has the first displacement guidance mechanism in this way, in the second step, in the case of coupling the first chassis member 5 and the second chassis member 4 with the opposing distance being adjusted, it is possible to save effort such as holding so that it does not shift in the Y-axis direction that is perpendicular with the opposing direction.

Next, the third step is performed. The present step is a step that secures the third chassis member 6 to the middle portion 2E of the outer periphery portion opposite the outer periphery portion that is sandwiched between the corner portions 2B, 2A of the liquid crystal panel 2.

First, as shown in FIG. 7, the third chassis member 6 is arranged so that the coupling portion 6C of the third chassis member 6 is at the back surface side of the liquid crystal panel 2 and on the Y-axis positive direction side, the securing portion 6A is on the Y-axis negative direction side, and the normal line of the lower-side surface securing portion 6b of the securing portion 6A follows the Y-axis direction.

Then, the third chassis member 6 is moved from the Y-axis negative direction side toward the positive direction side, and the end portion of the middle portion 2E on the lower side surface 2c side is inserted in the groove of each securing portion 6A. At this time, with regard to the position of the third chassis member 6 in the X-axis direction, the coupling portion 6C is arranged in a positional relation that overlaps the coupling portions 4C, 5C of the coupled body 8.

As shown in FIG. 9A, since the groove width formed by the front side pressing portion 6a and the rear side pressing portion 6f of the securing portion 6A is slightly wider than the width of the securing portion 6A in the Z-axis direction even between the plate surfaces of the flat spring portions 6d, 6g that are aligned with the front side pressing portion 6a and the rear side pressing portion 6f in the natural state, it is possible to easily perform insertion.

When the insertion proceeds, and the front side fixing surface 2e and the rear side fixing surface 2f of the middle portion 2E abut the hemispherical portions 6e, 6h, respectively, since the flat spring portions 6d, 6g undergo flexural deformation in the direction of the arrows c₁, c₂, c₃ of FIG. 9A, it is possible to continue insertion of each securing portion 6A.

By doing so in this manner, as shown in FIG. 1, it is possible to secure each securing portion 6A to the lower side surface 2c of the middle portion 2E.

Then, at the back surface of the liquid crystal panel 2, the arm portions 6B, 6C are arranged in a state of being extended in the direction along the Y-axis toward the center side of the liquid crystal panel 2. Also, the coupling portion 6C overlaps the coupling portions 4C and 5C of the coupled body 8 from the Z-axis direction negative direction side.

At this time, in the present exemplary embodiment, by inserting each projecting piece portion 6r that is provided at the coupling portion 6C in the rectangular holes 4r and 5r of the coupling portions 4C, 5c, it is possible to approximately position the coupling portion 6C in the X-axis direction. In this state, the positions of the slits 6m, 6n of the coupling portion 6C and the positions approximately agree in the X-axis direction with the cut and bent portions 4n, 5n that are projected out above the coupling portions 4C, 5C. For this reason, by further moving each securing portion 6A to the Y-axis position direction side, it is possible to insert the cut and bent portions 4n, 5n into the slits 6m, 6n from the Z-axis negative direction side.

By doing so, it is possible to secure the coupling portion 6C to the coupled body 8 in the X-axis direction and the Y-axis direction.

In this securing state, due to the flexural deformation of the flat spring 6d, 6g, the middle portion 2E receives the action of the resilient force to the Z-axis negative direction side and the Z-axis positive direction side from the hemispherical portions 6e, 6h, respectively. That is to say, the middle portion 2E is sandwiched by the flat spring portions 6d, 6g of each securing portion 6A in a state of the resilient force acting in the Z-axis direction, which is the plate thickness direction of the liquid crystal panel 2. For this reason, the middle portion 2E is also secured in the plate thickness direction by each securing portion 6A.

In this way, the flat spring portions 6d, 6g constitute a third resilient sandwiching portion that sandwiches the liquid crystal panel 2 by causing a resilient force to act on the liquid crystal panel 2 in the plate thickness direction at the middle portion 2E.

In the present step, since the securing portions 6A are secured in a state of the resilient force acting in the plate thickness direction, it is possible to maintain the state of the securing portions 6A being secured to the lower side surface 2c, which is a side surface on the outer periphery side.

However, since the securing state with the lower side surface 2c can be corrected by adjusting the facing distance in the fourth step described below, in the present step it may also be a temporary securing state that differs from the final securing state with respect to the lower side surface 2c. For example, the interval between the lower side surface 2c and the lower-side surface securing portion 6b may be in a securing state of uneven abutting, and may be somewhat shifted from the securing position.

With this, the third step is completed.

Next, the fourth step is performed. The present step is a step that mutually couples the coupled body 8 and the third chassis member 6 at the back surface side of the liquid crystal panel 2, in the state of the coupled body 8 that was formed in the second step and the third chassis member 6 that was secured to the middle portion 2E in the third step being respectively secured with the left side surface 2d and right side surface 2b, and the lower side surface 2c, which are side surfaces of the outer periphery side, at the corner portions 2B, 2A and the middle portion 2E, by adjusting the mutual facing distance.

In the present step, the coupled body 8 is pushed from the Y-axis positive direction side toward the Y-axis negative direction side with respect to the liquid crystal panel 2, and the third chassis member 6 is pushed from the Y-axis negative direction side toward the Y-axis positive direction side with respect to the liquid crystal panel 2. Thereby, the coupled body 8 and the third chassis member 6 respectively move in the Y-axis direction, and the facing distance between the coupled body 8 and the third chassis member 6 is adjusted.

As a result, the upper-side surface securing portions 4c, 5c of the coupled body 8 are reliably secured to the upper side surface 2a without looseness, and the lower-side surface securing portion 6b of the third chassis member 6 is reliably secured to the lower side surface 2c without looseness.

In this state, a positional relation comes about in which the female screw portions 4s, 5s of the coupling portions 4C, 5C overlap with the interior of the sliding holes 6p, 6q of the coupling portion 6C, respectively. Then, the fixing screws 7 are inserted via the sliding holes 6p, 6q and screwed together with the female screw portions 4s, 5s, whereby the fixing portions 4j, 5j of the coupling portions 4C, 5C and the fixing flange portions 6j, 6k of the coupling portion 6C are screw fastened.

At this time, since the sliding holes 6p, 6q of the coupling portion 6C are provided in an oblong shape that is long in the Y-axis direction, in the range of the long diameter dimension of the sliding holes 6p, 6q, it is possible to perform adjustment of the facing distance in the Y-axis direction between the coupled body 8 and the third chassis member 6.

For this reason, it is possible to secure the securing portion 6A without looseness in the Y-axis direction even if there are variations in the width of the liquid crystal panel 2 in the Y-axis direction due to machining errors.

By doing so, as shown in FIG. 1, the liquid crystal panel assembly body 1 is formed.

With this, the fourth step is completed.

In this way, the fixing portions 5j, 4j of the coupled body 8, and the fixing flange portions 6j, 6k of the coupling portion 6C constitute a second coupling fixing portion that mutually couples the coupled body 8 and the third chassis member 6 at the back side surface of the liquid crystal panel 2 by changing the facing distance with the corner portions 2B, 2A and the middle portion 2E.

In the present exemplary embodiment, the slits 6m, 6n are provided in a mutually parallel manner, and the long directions thereof are matched with the opposed directions of the coupled body 8 and the third chassis member 6 in the liquid crystal panel assembly 1. For this reason, in the state of the cut and bent portions 4n, 4m being inserted in the slits 6m, 6n, the relative displacement direction of the coupled body 8 and the third chassis member 6 is guided in mutually opposed directions. Accordingly, the slits 6m, 6n and the cut and bent portions 4n, 4m constitute a second displacement guiding mechanism that guides the relative displacement of the coupled body 8 and the third chassis member 6 in mutually opposed directions.

Since the present exemplary embodiment has the second displacement guide mechanism in this manner, in the case of coupling the coupled body 8 and the third chassis member 6 by adjusting the opposing distance in the fourth step, it is possible to eliminate the time and effort of holding them so as not to shift in the X-axis direction that is perpendicular to the opposed directions. For this reason, it is possible to easily and efficiently perform the work of adjusting the opposing distance and the coupling work.

As described above, according the fixing structure and method of fixing for a display panel of the present exemplary embodiment, it is possible to accurately fix the liquid crystal panel 2 even with the liquid crystal panel 2 that has no screw fastening holes for mounting, since it is possible to easily fix the liquid crystal panel 2 without looseness in the long direction and the short direction by coupling the first chassis member 5, the second chassis member 4, and the third chassis member 6 at the back surface side of the liquid crystal panel 2, in the state of being respectively secured to the corner portions 2B, 2A of the liquid crystal panel 2, and the middle portion 2E of the lower side surface 2c that is opposite the upper side surface 2a that is sandwiched by the corner portions 2B, 2A.

Note that the fixing structure for a display panel and method of fixing according to the present invention are not restricted to the constitution of the aforementioned exemplary embodiment, with substitutions and modifications of various constitutions being allowed as long as the gist of the present invention is not changed.

For example, in the foregoing description, a description was given with an example of the case of the first chassis member 5, the second chassis member 4, and the third chassis member 6 being provided with the first resilient sandwiching portion, the second resilient sandwiching portion, and the third resilient sandwiching portion, but in the case of the groove widths of the channel shapes of the securing portions 5A, 4A, 6A and the widths of the corner portions 2B, 2A and the middle portion 2E in the Z-axis direction being formed with dimensions to be able to mutually fit with high accuracy, they may have constitutions in which any or all of the first resilient sandwiching portion, the second resilient sandwiching portion, and the third resilient sandwiching portion are eliminated.

Also, in the aforementioned description, a description was given of the case of the first coupling fixing portion and the second coupling fixing portion including the first displacement guiding mechanism and the second displacement guiding mechanism, but for cases in which there is no hindrance to the coupling work, they may have constitutions in which either or both of the first displacement guiding mechanism and the second displacement guiding mechanism are eliminated.

Also, in the aforementioned description, a description was given by the example of the case of the first resilient sandwiching portion, the second resilient sandwiching portion, and the third resilient sandwiching portion being constituted by the flat spring portions 5d, 5g, 4d, 4g, 6d, 6g that are integrally formed with the securing portions 5A, 4A, 6A, respectively, but provided the first resilient sandwiching portion, the second resilient sandwiching portion, and the third resilient sandwiching portion have constitutions that can cause a resilient force to act, they are not limited to flat spring constitutions. For example, they may use an elastic body such as rubber or the like, or the entire groove side surfaces of the securing portions 5A, 4A, 6A may be constituted to deform to cause a resilient force to act.

Also, in the aforementioned description, a description was given by the example of the case of the hemispherical portions 5e, 5h, 4e, 4h, 6e, 6h being provided to project out at the flat spring portions 5d, 5g, 4d, 4g, 6d, 6g, and a resilient force acting on the front side fixing surface 2e and the rear side fixing surface 2f by these, but provided the projections that are provided at the flat springs can allow the securing portions 5A, 4A, 6A to smoothly fit the liquid crystal panel 2, they are not limited to hemispherical shapes. For example, other projection shapes may be used such as a cylindrical shape, a truncated cone shape, a semi-ellipsoid shape, a truncated pyramid shape, or the like.

Also, in the foregoing description, the second coupling fixing portion was described by the example of the case of being provided with the first chassis member and second chassis member, and the third chassis member, but provided the second coupling fixing portion is capable of changing the opposing distance between the coupled body and the third chassis member, it may be provided with either of the first chassis member and second chassis member, and with the third chassis member.

Also, in the foregoing description, the first chassis member 5, the second chassis member 4, and the third chassis member 6 were described by the example of the case of all being manufactured by press working a metal plate, but for example molded products may be adopted for the first chassis member 5, the second chassis member 4, and the third chassis member 6. Also, the material is not limited to metal, and a synthetic resin, or a composite material of a synthetic resin and metal may be used.

Also, in the foregoing description, the shape of the channel of the securing portions 5A, 4A, 6A of the first chassis member 5, the second chassis member 4, and third chassis member 6 was described by the example of the case of being formed in an elongated manner along the outer periphery portion of the liquid crystal panel 2 since it is long compared to the plate thickness of the liquid crystal panel 2. This is only an example, and the length of the groove portion of the securing portions 5A, 4A, 6A is not particularly limited, provided it is possible to fix the liquid crystal panel 2 from the side surface side by securing the side surface of the outer periphery side of the liquid crystal panel 2.

Accordingly, the length of the left-side surface securing portion 5b, the right-side surface securing portion 4b, and the lower-side surface securing portion 6b in the “long direction” referred to above may be made the plate thickness or less of the liquid crystal panel 2.

Also, in the foregoing description, the first chassis member 5 and the second chassis member 4 were described by the example of the case of having approximately plane-symmetrical shapes, but the shapes of the first chassis member 5 and the second chassis member 4 may also be shapes that differ from plane symmetrical. That is to say, provided the securing positions of the first chassis member 5, the second chassis member 4, and the third chassis member 6 are the corner portions 2A, 2B and the middle portion 2E, respectively, the shapes of the securing portions 4A, 5A, 6A may mutually differ. Also, the first chassis member 5, the second chassis member 4, and the third chassis member 6 may be coupled to positions that differ from the foregoing description, for example, positions separated from the center of the liquid crystal panel 2 in the X-axis direction at the back surface side of the liquid crystal panel 2.

While preferred exemplary embodiments of the invention have been described above, but the present invention is not limited to the aforementioned exemplary embodiments and modifications. Additions, omissions, substitutions, and other modifications can be made without departing from the spirit or scope of the present invention. The invention is not limited by the foregoing description, and is only limited by the scope of the appended claims.

### INDUSTRIAL APPLICABILITY

The present invention relates to a fixing chassis for a display panel such as a liquid crystal panel, and a method of fixing.

The present invention provides a fixing chassis for a display panel that can accurately and easily fix even a display panel that does not have screw fastening holes for mounting, and a method of fixing.

### REFERENCE SYMBOLS

1 Liquid crystal panel assembly

2 Liquid crystal panel (display panel)

2A Corner portion (first corner portion)

2B Corner portion (second corner portion)

2C, 2D Corner portion

2E Middle portion

2a Upper side surface

2b Right side surface

2c Lower side surface

2d Left side surface

2e Front side fixing surface

2f Rear side fixing surface

3 Fixing chassis

4 Second chassis member

4A Securing portion (second corner securing portion)

4B, 5B Arm portion

4C, 5C, 6C Coupling portion

4K, 4M, 5k, 5m Projecting piece portion

4a, 5a, 6a Front-side pressing portion

4b Right-side surface securing portion

4c, 5c Upper-side surface securing portion

4d, 4g, 5d, 5g, 6d, 6g Flat spring portion

4e, 4h, 5e, 5h, 6e, 6h Hemispherical portion

4f , 5f Rear-side pressing portion

4i, 5i, 6i Plate-like portion

4j, 5j Fixing portion

4n, 5n Cut and bent portion

4s, 4v, 4w, 5s Female screw portion

4t, 4u Fixing surface

5 First chassis member

5A Securing portion (first corner securing portion)

5b Left-side surface securing portion

5p, 5q, 6p, 6q Sliding hole

6 Third chassis member

6A Securing portion (opposing side securing portion)

6b Lower-side surface securing portion

6i Plate-like portion

6j, 6k Fixing flange portion

6m, 6n Slit

6s Coupling portion main body

8 Coupled body

1. A fixing structure for a display panel having a rectangular plate shape, the display panel performing image display at a front side, the fixing structure comprising:
a first chassis member that includes at one end portion a first corner securing portion secured to two side surfaces on an outer periphery side of a first corner portion of the display panel;
a second chassis member that includes at one end portion a second corner securing portion secured to two side surfaces on an outer periphery side of a second corner portion of the display panel that is adjacent to the first corner portion; and
a third chassis member that includes at one end portion an opposing side securing portion secured to a middle portion of a side surface on an outer periphery side of the display panel that opposes a side surface on an outer periphery side that is sandwiched between the first corner portion and the second corner portion,
other end portions of the first chassis member, the second chassis member, and the third chassis member being coupled to each other at a back surface side of the display panel.

2. The fixing structure for a display panel according to claim 1, wherein:
the first chassis member includes at the one end portion a first resilient sandwiching portion that sandwiches the display panel by causing a resilient force to act in a plate thickness direction of the display panel at the first corner portion;
the second chassis member includes at the one end portion a second resilient sandwiching portion that sandwiches the display panel by causing a resilient force to act in the plate thickness direction of the display panel at the second corner portion; and
the opposing side securing portion includes at the one end portion a third resilient sandwiching portion that sandwiches the display panel by causing a resilient force to act in the plate thickness direction of the display panel at the middle portion.

3. The fixing structure for a display panel according to claim 1, wherein:
a first coupling fixing portion is provided at the other end portions of the first chassis member and the second chassis member, the first coupling fixing portions changes an opposing distance between the first corner securing portion and the second corner securing portion, and couples the first chassis member and the second chassis member with each other at the back surface side of the display panel to form a coupled body including the first chassis member and the second chassis member; and
a second coupling fixing portion is provided at the other end portion of at least either one of the first chassis member and the second chassis member, and at the other end portion of the third chassis member, the second coupling fixing portion that changes an opposing distance between the first corner securing portion and second corner securing portion, and the opposing side securing portion, and couples the coupled body and the third chassis member with each other at the back surface side of the display panel.

4. The fixing structure for a display panel according to claim 3, wherein:
the first coupling fixing portion includes a first displacement guiding mechanism that guides relative displacement of the first chassis member and the second chassis member in a direction in which the first chassis member and the second chassis member are opposed to each other; and
the second coupling fixing portion includes a second displacement guiding mechanism that guides relative displacement of the coupled body and the third chassis member in a direction in which the coupled body and the third chassis member are opposed to each other.

5. The fixing structure for a display panel according to claim 2, wherein the first resilient sandwiching portion, the second resilient sandwiching portion, and the opposing side resilient sandwiching portion include a flat spring portion that causes the resilient force to act.

6. A method of fixing a display panel in which a display panel having a rectangular shape and performing image display at a front side is fixed using a fixing chassis, the fixing chassis including a first chassis member, a second chassis member, and a third chassis member that can be mutually coupled and can be secured to side surfaces on an outer periphery side of the display panel, the method comprising:
a first step of securing the first chassis member to a first corner portion of the display panel, and securing the second chassis member to a second corner portion of the display panel that is adjacent to the first corner portion;
a second step of forming a coupled body including the first chassis member and the second chassis member by coupling the first chassis member and the second chassis member respectively secured to the display panel in the first step, at a back surface side of the display panel, in a state of being secured to at least a mutually opposed pair of side surfaces on the outer periphery side of the display panel by adjusting an opposing distance between the first chassis member and the second chassis member;
a third step of securing the third chassis member to a middle portion of an outer periphery portion of the display panel that opposes an outer periphery portion sandwiched between the first corner portion and the second corner portion; and
a fourth step of coupling the coupled body and the third chassis member with each other at the back surface side of the display panel in a state of the coupled body formed in the second step and the third chassis member secured to the middle portion in the third step being respectively secured to the first corner portion and the second corner portion, and a side surface on the outer periphery side at the middle portion by adjusting an opposing distance between the coupled body and the third chassis member.
